(19) United States
(12) Patent Application Publication
(10) Pub. No.: US 2011/0240123 A1
(43) Pub. Date: Oct. 6, 2011

(54) Photovoltaic Cells With Improved Electrical Contact

(76) Inventors: Hao LIN, Rochester, NY (US); Wei Xia, Rochester, NY (US); Hsiang Ning Wu, Rochester, NY (US); Ching Wan TANG, Brighton, NY (US)

(21) Appl. No.: 12/751,516

(22) Filed: Mar. 31, 2010

(51) Int. Cl. H01L 31/00

(52) U.S. Cl. 136/260; 136/261

(57) ABSTRACT

A photovoltaic cell comprising a metal oxide back buffer layer. Improved n-CdS/p-CdTe heterojunction photovoltaic cells comprising a metal oxide buffer layer for making low-resistance electrical contact to the p-type CdTe layer. The back buffer layer comprises metal oxides having a high work function.

### FIELD OF THE INVENTION

The present invention generally relates to the structure and production of photovoltaic cells. More particularly, the invention relates to structure of and production of CdS/CdTe thin-film photovoltaic cells.

### BACKGROUND OF THE INVENTION

Polycrystalline n-CdS/p-CdTe heterojunction solar cells are attractive for large-scale, terrestrial electricity generation. In order to achieve high efficiency in a solar cell, the CdS/CdTe heterojunction structure is often subjected to additional bulk and surface treatments subsequent to the deposition of the CdS and CdTe layers. These treatment steps are needed to improve the crystalline quality of the CdTe thin film and to produce a chemically modified CdTe surface for making ohmic or low-resistance electrical contact.

An established process suitable for the manufacture of high-efficiency CdS/CdTe solar cells is as follows: in sequence, CdS and CdTe layers are deposited in a vacuum chamber by a close-space sublimation method (CSS) on a transparent conducting oxide (TCO) substrate, such as tin oxide coated soda lime glass, which also forms the front contact electrode through which the solar cell is illuminated. Following the CdS/CdTe deposition, the substrate/TCO/CdS/CdTe structure is annealed in CdCl₂ vapor at an elevated temperature. Following the CdCl₂ vapor treatment, the exposed surface of the p-CdTe layer is treated in an etching solution to form a Te-rich surface, which is essential in forming low-resistance back contact to the p-CdTe. The cell is then completed with the deposition of the back electrode, which is typically an evaporated layer of metal or a screen-printed layer of a conductive paste.

Although it is expected that a high work function metal such as Au or Ni would be useful providing the low-resistance contact to the p-CdTe, in practice such metal/p-CdTe contacts are not useful because they can cause degradation in the solar cell during operation or at elevated temperature due to chemical reaction or metal diffusion. To address the instability of the p-CdTe/back electrode interface, the p-CdTe is subjected to a wet process, known as NP treatment, where the CdTe film is dipped in a mixture of nitric and phosphoric acid solutions. This process has been adopted as a standard process in CdS/CdTe solar cell fabrication, but again, it necessitates a wet processing step. (Tyan U.S. Pat. No. 4,319,063)

The solution etching step, which involves dipping the substrate/TCO/CdS/CdTe structure in a nitric/phosphoric acid bath (known as NP treatment) for a short time, necessitates its removal from the vacuum chamber and therefore can, cause process interruption and inefficiency in the cell fabrication. It would be advantageous to carry out the entire CdS/CdTe cell fabrication process from the beginning to the finish using an in-line physical vapor deposition process, and this would require the elimination of the solution NP treatment step and the development of a new CdTe surface treatment step that is compatible with the in-line process.

Based on the foregoing, there exists an ongoing and unmet need for a viable photovoltaic cell fabrication process which can be carried out without the need for wet processing steps.

### BRIEF SUMMARY OF THE INVENTION

The present invention provides a device structure for photovoltaic cells. The photovoltaic cells of the present invention have the advantages such as, for example, high efficiency, improved contact properties such as achieving low-resistance contact to the p-type semiconductor layer in photovoltaic cells (e.g., p-CdTe), eliminating a solution processing step in the cell fabrication process and improving the cell fabrication throughput by using a continuous dry process (e.g., in-line physical vapor deposition process) for all the cell layers.

In one embodiment, the present invention provides a device structure for CdS/CdTe photovoltaic cells. The device comprises a layer of metal oxide, MOₓ, as the back buffer layer in a device structure comprising, in sequence,

a) a semitransparent substrate,

b) a semitransparent front electrode,

c) a layer of CdS,

d) a layer of CdTe,

e) a layer of MOₓ, and

f) a back electrode.

The MOₓ buffer layer can be, for example, a metal oxide with a work function higher than 5.8 eV. The metal oxide can, for example, be a stoichiometric or non-stoichiometric metal oxide.

### BRIEF DESCRIPTION OF THE FIGURES

FIG. 1. Schematic description of layer configuration and material compositions of CdS/CdTe solar cells of this invention.

FIG. 2. Graphical representation of current-voltage characteristics of CdS/CdTe cells with and without a stoichiometric or non-stoichiometric molybdenum oxide, MoOₓ, back buffer layer.

FIG. 3. Graphical representation of current-voltage characteristics of CdS/CdTe cells with and without a stoichiometric or non-stoichiometric nickel oxide, NiOₓ back buffer layer.

FIG. 4. Graphical representation of current-voltage characteristics of CdS/CdTe cells with a back buffer layer produced by NP treatment.

FIG. 5. Graphical representation of current-voltage characteristics of CdS/CdTe cells with a MoOₓ back buffer layer.

FIG. 6. Graphical representation of current-voltage characteristics of CdS/CdTe cells with MoOₓ as the back buffer layer and various metals as the back electrode.

### DETAILED DESCRIPTION OF THE INVENTION

The present invention provides a device structure for photovoltaic cells. The present invention also provides a method for fabrication of such cells.

In one aspect, the present invention provides a device structure with a back buffer layer between the semiconductor and back electrode comprising a metal oxide, MOₓ. A metal oxide layer can be deposited by any method known in the art, such as, for example, vapor deposition.

Some of the advantages of this invention include: a) achieving high efficiency in photovoltaic (e.g., CdS/CdTe) cells, b) improved contact properties such as achieving low-resistance contact to the p-type semiconductor layer in photovoltaic cells (e.g., p-CdTe), c) eliminating a solution processing step in the cell fabrication process, and d) improving the cell fabrication throughput by using a continuous, dry process (e.g., in-line physical vapor deposition process) for all the cell layers.

In one embodiment the present invention provides a photovoltaic cell comprising: a) a transparent (or semitransparent) substrate, b) a semitransparent front electrode, c) a front buffer layer, d) a layer of n-type semiconductor, e) a layer of p-type semiconductor, f) a back buffer layer, and g) a back electrode.

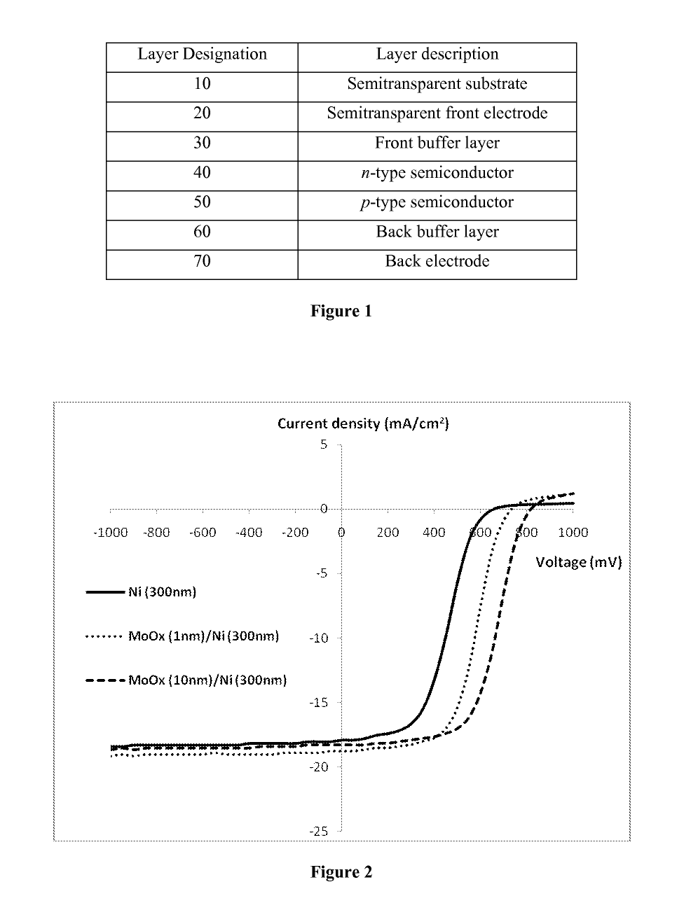

For example, in general, a basic CdS/CdTe solar cell of the present invention comprises a layer of n-type semiconductor (e.g., CdS) and a layer of p-type semiconductor (e.g., CdTe). Sandwiching these two layers are the front electrode, which is in contact with the n-type semiconductor, and a back electrode, which is in contact with the p-type semiconductor. These layers are formed on a transparent substrate. Thus, in one embodiment, the present invention provides a CdS/CdTe photovoltaic cell with a device structure comprising, in sequence, a) a semitransparent substrate, b) a semitransparent front electrode, c) a layer of CdS, d) a layer of CdTe, e) a layer of MOₓ and f) a back electrode. FIG. 1 is a graphical representation of an example of a CdS/CdTe photovoltaic cell of the present invention.

A substrate (e.g., substrate 10 of the CdS/CdTe photovoltaic cell depicted graphically in FIG. 1) is in direct contact with the front electrode and light impinges on the cell through the substrate. Thus, the substrate is necessarily transparent or semitransparent. By semitransparent, it is meant that the substrate transmits 50% or greater of light in the solar radiation range, i.e., 400 nm to 1400 nm. The optical transmission of the glass substrate is usually better than 95% over the wavelength region from 400 nm to 1000 nm. Typically, a thin glass is used because it can endure the process temperature for the photovoltaic cell fabrication, which is typically in excess of 500° C. Any substrate transparent or semitransparent material meeting the requisite processing requirements can be used. It is preferable to use soda-lime glass because of its low cost.

A front electrode is in direct contact with the substrate (e.g., front electrode 20 of the CdS/CdTe photovoltaic cell depicted graphically in FIG. 1). The front electrode is typically a transparent conducting oxide (TCO) layer, but any transparent conducting material with the necessary properties (e.g., conductivity and transparency) can be used. It is preferable that the front electrode have an optical transmission of better than 90% over the wavelength region from 400 nm to 1000 nm. For example, a TCO layer is deposited on top of a glass substrate by a physical deposition method, such as sputtering. For example, fluorine doped tin oxide, SnO₂:F, can be used as a front electrode. It is preferable to use fluorine doped tin oxide due to its high electrical conductivity and high temperature tolerance. With SnO₂:F as the TCO, the thickness range of the front electrode layer is typically between 100 nm and 1000 nm. Other examples of TCO materials include, but are not limited to, indium tin oxide (ITO), aluminum-doped zinc oxide (ZnO:Al), and other mixed oxides such as aluminum doped zinc gallium oxide.

A front buffer layer comprises a semi-insulating, wide-bandgap material. The front buffer layer is in contact with front electrode (e.g., front buffer layer (30) is deposited on top of the TCO layer 20 in FIG. 1). The primary function of this buffer layer is to minimize the probability of direct contact between the front electrode, e.g., TCO layer 20, and p-semiconductor layer, e.g., CdTe layer 50, via the n-type semiconductor layer, e.g., CdS layer 40. This layer is very thin, typically less than 100 nm, and largely transparent. Typically, this buffer layer, for example an undoped SnOₓ, is deposited using physical vapor deposition, such as sputtering. Other suitable front buffer layer materials include, but are not limited to, zinc stannate (Zn₂SnO₄), indium oxide (In₂O₃) and zinc oxide (ZnO). This buffer layer is optional in the construction of photovoltaic cells, e.g., CdS/CdTe solar cells. For example, functional solar cells can be made without this buffer layer.

An n-type semiconductor layer, whose primary function is to form a heterojunction with the p-type semiconductor layer, e.g. CdTe layer 50, is in contact with the front buffer layer or front electrode. Any n-type semiconductor material with the appropriate band gap can be used. The n-type semiconductor should have a band gap greater than that of the p-type semiconductor layer. Also, the band gap should be such that the n-type semiconductor layer does not absorb incident light. The typical thickness of the n-type semiconductor layer, e.g., CdS layer, is about 100 nm or less. The thickness of the n-type semiconductor layer is usually kept as low as possible to permit maximum light transmission in this layer and therefore maximum light absorption in the n-type/p-type (e.g., CdS/CdTe) heterojunction region and in the bulk of the p-type (e.g., CdTe layer), where charge generation takes place.

In one embodiment, the n-type semiconductor is cadmium sulfide or an alloy of cadmium sulfide. For example, a cadmium sulfide alloy can be formed by at least partially replacing Cd with Zn, Mg, Mn, or the like. As another example, a cadmium sulfide alloy can be formed by at least partially replacing sulfide with Te, Se, O, or the like.

For example, in FIG. 1, the n-type semiconductor layer is CdS layer 40 and it is deposited on top of the front buffer layer 30. The n-type semiconductor layer, e.g., CdS layer, can be deposited by a variety of methods, including chemical bath deposition, sputtering, and close-space sublimation. In one embodiment, a chemical bath deposition method was used (see Examples). When CdS is used, which has a bandgap of 2.42 eV, is the n-type semiconductor layer, light with a wavelength shorter than 500 nm will be appreciably absorbed by this layer. Other n-type II-VI semiconductors with a wider bandgap, such as, but not limited to, ZnO, ZnS, ZnSe and Cd₁₋ₓZnₓS, can also be used as the n-type semiconductor.

It is preferable to use n-type and p-type semiconductors that have good lattice match. For example, CdS is the preferred material when CdTe is the p-type semiconductor because it has a better lattice match with CdTe.

A p-type semiconductor is in contact with the n-type semiconductor forming a p-n heterojunction. The function of the p-type semiconductor (e.g., CdTe layer) is to form a p-n heterojunction structure (e.g., CdS/CdTe structure) with the n-type semiconductor layer (e.g., CdS layer) and to serve as the active absorber layer in the solar cell for capturing sunlight. The p-type semiconductor layer can be any II-VI semiconductor. For example, in FIG. 1, the p-type semiconductor layer (50) is a II-VI semiconductor, including, for example, CdTe, ZnTe, Cd₁₋ₓZnₓTe, Cd₁₋ₓHgₓTe, Cd₁₋ₓMgₓTe, Cd₁₋ₓMnₓTe, Cu(In,Ga)Se₂ and Cu(In,Al)S₂. It is preferable that the p-type semiconductor has a bandgap energy which matches (or at least overlaps significantly) with the wavelengths of the incident radiation. For example, CdTe is a preferred p-type semiconductor because it has a bandgap which matches the energy profile solar radiation. For example, in the fabrication of a CdS/CdTe photovoltaic cell, the p-CdTe layer is deposited on top of the n-CdS layer. The typical thickness of the p-type semiconductor layer, e.g., p-CdTe layer, is about 4 to 8 μm.

In one embodiment, the p-type semiconductor is cadmium telluride or an alloy of cadmium telluride. For example, a cadmium telluride alloy can be formed by at least partially replacing Cd with Zn, Mg, Mn, or the like. As another example, a cadmium sulfide alloy can be formed by at least partially replacing telluride with S, Se, O, or the like.

Any of the methods known in the art can be used to deposit this layer, including, for example, sputtering and close-space sublimation. Close-space sublimation is preferred because it is capable of depositing a crystalline CdTe film at very high deposition rates. In one embodiment, close-space sublimation was used to deposit the p-type semiconductor layer (see Examples). To produce a p-type CdTe film using the close-space sublimation method, it is necessary to use oxygen as a carrier gas. Without intending to be bound by any particular theory, it is considered that the oxygen carrier gas acts as p-type dopant in CdTe.

To further improve the performance of CdS/CdTe photovoltaic cells, a CdCl₂ treatment can, optionally, be applied after CdTe deposition. Such treatment can, for example, improve the film crystallinity, increase the grain size, introduce shallow dopants, and reduce lattice mismatch between CdS and CdTe.

The various layers can, optionally, be subjected to post-deposition processing. For example, in the case of the CdTe layer, after CdCl₂ treatment, it is may be necessary to remove residual CdCl₂ and other surface contaminants, e.g., by thermally annealing the CdS/CdTe film in vacuum or by cleaning with deionized water.

A back buffer layer is a metal oxide of suitable work function. In one embodiment, the back buffer layer comprises stoichiometric or non-stoichiometric metal oxide, e.g., molybdenum oxide, MoOₓ, (where x is equal to or less than 3), and has a work function of 10% or higher than that of the p-type semiconductor with which it makes contact.

The term work function, according to a standard text book, e.g., S. M. Sze, Physics of Semiconductor Devices, 2^{nd} Edition, Wiley Science, 1981, pages 250-251, is the minimum energy necessary for an electron to escape into vacuum measured from the Fermi level of the material. For a metal oxide, the Fermi level resides in between the conduction band and valence band, and therefore could have a large range of values that depend on several factors, one factor being the specific stoichiometric composition of the metal oxide. The higher is the work function for the metal oxide, the lower is energy barrier for hole injection from the metal oxide to the valence band of the p-type semiconductor. Thus, the contact formed between a high work function metal oxide and a p-type semiconductor can in a limit become ohmic, i.e., possessing little electrical resistance, when the work function of the metal oxide is higher than that of the p-type semiconductor. Further, the work function of the metal oxides can be sensitive to the stoichiometric composition and surface contamination. For MoOₓ, for instance, the work function values can range from 4.9 to 6.8 eV, depending on the method of preparation and the history of MoOₓ film exposure to contaminating environments (e.g., atmosphere). It is understood that it is the alignment of the work function of the metal oxide with that of the p-type semiconductor, e.g., p-CdTe, that determines the contact energy barrier. This is to be distinguished from the use of very thin insulating film, including metal oxide films, for producing low-barrier contact, where the insulating film behaves as a tunneling channel for electrons or holes to pass from a contacting metal to the semiconductor or vice versa.

The function of this buffer layer is to provide an improved low-resistance contact between the p-type semiconductor, e.g., CdTe layer 50, and the back electrode, e.g., the back electrode 60 in FIG. 1. It is deposited on top of the p-type semiconductor layer, e.g., p-CdTe layer 50.

In the present invention, a class of metal oxides has been found to be useful as the back buffer layer material for the back electrode in photovoltaic cells, e.g., CdS/CdTe solar cells. These metal oxides generally include transition metal oxides, including, for example, molybdenum oxide, nickel oxide, tungsten oxide, vanadium oxide and tantalum oxide. Thus, in various embodiments, the metal oxide includes metal oxides including, for example, MoOₓ, WOₓ, VOₓ, TaOₓ, and NiOₓ, where the subscript x indicates either stoichiometric or nonstoichiometric composition for the metal oxides. A necessary criterion for these oxides is that they have a work function that matches that of the p-type semiconductor material, e.g., p-CdTe which has a work function of 5.8 eV.

In one embodiment, the metal oxide work function matches that of the p-type semiconductor when the metal oxide work function is equal to or greater than the work function of the p-type semiconductor. In various embodiments, the metal oxide work function matches that of the work function of the p-type semiconductor when the metal oxide work function is 1 to 10%, including all integers between 1 and 10%, or greater than the work function of the p-type semiconductor.

The thickness of the metal oxide back buffer layer is 1 to 100 nm, including all integers therebetween. In one embodiment, the thickness of a MoOₓ back buffer layer applied to p-CdTe can be 1 to 100 nm, including all integers therebetween, and the work function of the MoOₓ layer can be varied from 4.9 eV to 6.8 eV, depending on the deposition conditions. Generally, the work function is related to the oxygen content of the metal oxide. For example, for MoOₓ the work function increases with increasing oxygen content.

In one embodiment, the back buffer layer is amorphous. For example, amorphous MoOₓ can be used as a back buffer layer. In another embodiment, the back buffer layer is crystalline. For example, as-deposited amorphous MoOₓ can be annealed at a high temperature (>200° C.) such that it crystallizes.

Any of the deposition methods known in the art can be used to deposit the back buffer layer. Examples include, but are not limited to, physical vapor deposition and atomic layer epitaxy. A preferred deposition method for fabrication of the back buffer layer is physical vapor deposition, which includes, for example, sputtering, e-beam and resistive heating methods.

The present invention provides a desirable alternative to the NP treatment by using a metal oxide buffer layer that can be conveniently deposited by a variety of physical vapor deposition methods, including sputtering, e-beam and resistive heating. Thus, the process for the fabrication of the solar cell will not require a wet process, as in the NP treatment, and can therefore be streamlined to include only dry processes, e.g., vapor deposition, for all the layers.

A back electrode is in contact with the back buffer layer. For example, in FIG. 1, the back electrode (70) is an evaporated metal film deposited on the buffer layer (60). The back electrode can be deposited by a variety of physical vapor deposition methods, including, for example, sputtering, e-beam and resistive heating methods. Generally, after deposition of a back buffer layer and a back electrode, no further annealing process is necessary to produce an ohmic back contact. There is no limitation on the thickness or optical transparency of the back electrode layer. The back electrode layer thickness is typically greater than 200 nm, which provides adequate conductivity. Most metals can be used, including, for example, common metals such as Cu, Ag, Au, Al, Ni, Fe, and Mo, and metal alloys such as stainless steel and those including the aforementioned common metals. The preferred back electrode materials include, for example Ni and stainless steel, as they are abundant and relatively inexpensive. CdS/CdTe solar cells fabricated according to the present invention using the preferred back buffer layer materials and the preferred back electrode materials are found to be stable with respect to device operation.

The present invention provides a system for generating electrical energy. In one embodiment, the present invention provides a solar cell comprising the photovoltaic cells of the present invention, a electrical connection connected to the front electrode and a electrical connection to the back electrode. In one embodiment, the system comprises a plurality of photovoltaic cells.

In another embodiment, the photovoltaic cells of the present invention are used to generate electricity by converting photons to electrical charge carriers. For example, a photovoltaic cell of the present invention can be used to generate electricity by impinging photons of the appropriate wavelength (e.g., sunlight) on the cell resulting in the generation of charge carriers and thus, electrical current.

Devices fabricated according to the present invention exhibit improved performance. For example, devices with a metal oxide back buffer layers exhibit improved performance relative to devices fabricated without such back buffer layers or devices fabricated using wet-processing methods, such as the NP method. Examples of improved performance include, but are not limited to, increased current density, open circuit voltage, fill factor and/or efficiency.

In another aspect, the present invention provides a method of improving the electrical contact between a semiconducting material and an electrode material. In one embodiment, the method improves the electrical contact between a p-type semiconductor layer and metal electrode layer in, for example, a photovoltaic cell, by depositing a metal oxide layer on the p-type semiconductor layer and subsequently depositing a back electrode layer such as a metal layer.

In another aspect, the present invention provides a method of fabrication to produce photovoltaic cells where all of the steps are dry (i.e., no wet processing steps are required). In one embodiment, all of the steps in the process are carried out under vacuum. Optionally, all of the steps can be carried out in the same apparatus.

The following examples are presented to illustrate the present invention. They are not intended to limiting in any manner.

### Example 1

### Comparison of Photovoltaic Cells Fabricated with and without a Back Buffer Layer

CdS/CdTe photovoltaic cells were prepared using a process described as follows. Commercially available soda lime glass with SnO₂:F coating was used as the substrate. A layer of CdS film was deposited on top of the substrate using chemical bath deposition method as described by Chu et al. in “Solution-Grown Cadmium Sulfide Films for Photovoltaic Devices”, Journal of Electrochemical Society, vol. 139, pp. 2443-2446 (1992). CdTe film was deposited on top of CdS using a close-space sublimation method as described by Tyan in “Topics on Thin Film CdS/CdTe Solar Cells”, Solar Cells, vol. 23, pp. 19-29 (1988). Following the CdTe deposition, a cadmium chloride vapor treatment step was performed in a method as described by McCandless et al. in “Optimization of Vapor Post-deposition Processing for Evaporated CdS/CdTe Solar Cells”, Progress in Photovoltaics, vol. 7, pp. 21-30 (1999). After the cadmium chloride treatment, a back electrode, nickel, was deposited by vapor deposition onto the CdTe to form the back electrode. This completed the fabrication of the reference cell without the back buffer layer. For cells with the back buffer layer, the buffer layer was deposited on the CdTe by either sputtering or resistive thermal deposition, prior to the deposition of the back electrode.

Current-voltage (J-V) traces for the photovoltaic cells under illumination were obtained using a solar simulator with light intensity of about 80 mW/cm². Photovoltaic performance parameters: open-circuit voltage (V_{OC}), short-circuit current density (J_{SC}), fill factor (FF) and cell efficiency (η_{eff}) were calculated from the J-V traces. The value of short-circuit current density was normalized with the equivalent of Air Mass 1.5 global illumination of 100 mW/cm².

FIG. 2 shows the J-V characteristics of a CdS/CdTe reference cell without the back buffer layer, and CdS/CdTe cells with 1 nm and 10 nm MoOₓ as the back buffer layer. The photovoltaic performance parameters for these cells are shown in Table 1. It is clear that there are substantial improvements in all performance parameters for cells with a back buffer layer of MoOₓ. The improvement in efficiency over the reference cell is 40% and 63% for cells with 1 nm and 10 nm of MoOₓ respectively.

TABLE 1
Device performance parameters of CdS/CdTe photovoltaic cells with
and without a MoOₓ, back buffer layer

| Back buffer | Thickness | | | | |
|---|---|---|---|---|---|
| layer | of Ni | | | | |
| (thickness, | electrode | J_{SC} | V_{OC} | FF | η_{eff} |
| nm) | (nm) | (mA/cm²) | (mV) | (%) | (%) |
| None | 300 | 17.9 | 655 | 47 | 5.5 |
| MoOₓ (1) | 300 | 18.8 | 740 | 55 | 7.7 |
| MoOₓ (10) | 300 | 18.3 | 820 | 60 | 9.0 |

### Example 2

### Example of Photovoltaic Cells Fabricated with and without a Nickel Oxide, NiOₓ, Back Buffer Layer

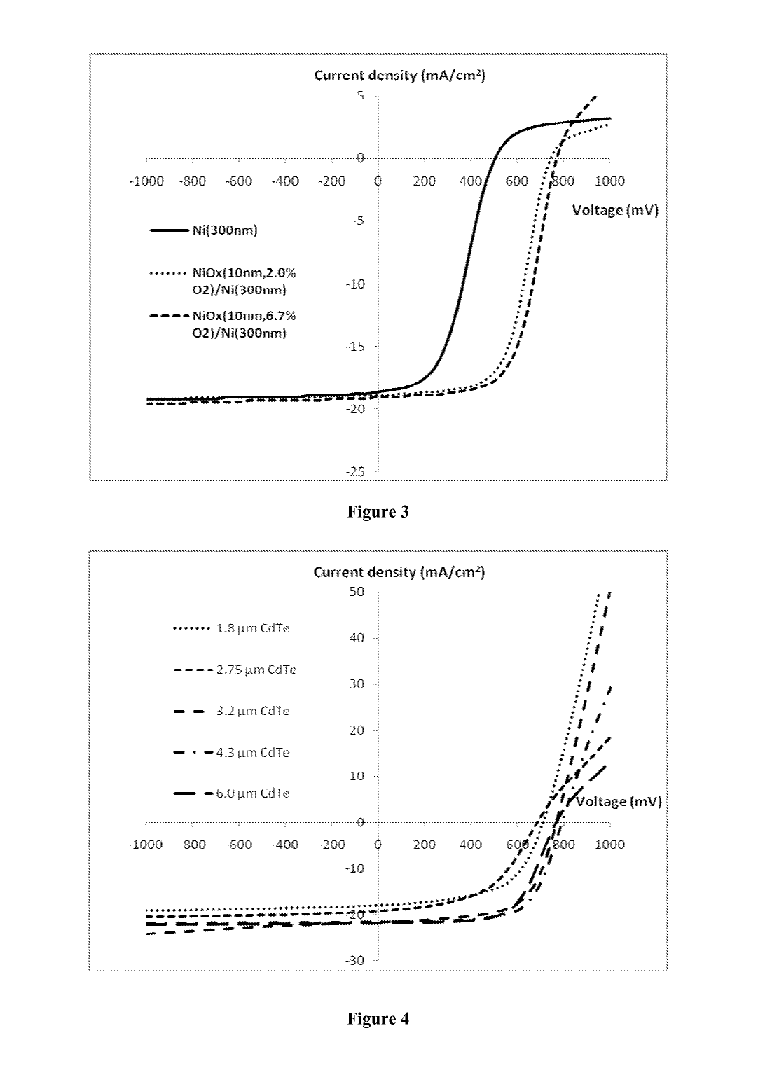

CdS/CdTe photovoltaic cells were prepared as described in Example 1, except that NiOₓ was used as the back buffer layer instead of MoOₓ. The NiOₓ layer was deposited on top of the p-CdTe layer by reactive sputtering in a mixture of oxygen and argon. FIG. 3 shows the J-V characteristics of a CdS/CdTe reference cell without the NiOₓ, back buffer layer, a CdS/CdTe cell with 10 nm NiOₓ deposited in an atmosphere containing 2.0% O₂ as the back buffer layer, and a CdS/CdTe cell with 10 nm NiOₓ deposited in an atmosphere containing 6.7% O₂ as the back buffer layer. The performance parameters for these cells are shown in Table 2. It is clear that there are substantial improvements in all performance parameters for cells with a buffer layer of NiOₓ. The improvement in efficiency over the reference cell is 97% and 109% for cells with two different NiOₓ buffer layers, respectively.

TABLE 2
Device performance parameters of CdS/CdTe photovoltaic
cells with and without a NiOₓ back buffer layer.

| Back buffer | O₂:Ar | Thickness | | | | |
|---|---|---|---|---|---|---|
| layer | pressure | of Ni | | | | |
| (thickness, | ratio in | electrode | J_{SC} | V_{OC} | FF | η_{eff} |
| nm) | deposition | (nm) | (mA/cm²) | (mV) | (%) | (%) |
| None | — | 300 | 18.6 | 505 | 46 | 4.3 |
| NiOₓ (10) | 2.0% | 300 | 18.9 | 747 | 60 | 8.5 |
| NiOₓ (10) | 6.7% | 300 | 19.0 | 777 | 61 | 9.0 |

### Example 3

### Control

### Back Buffer Layer Produced by NP Treatment

In this example, the back buffer layer for the CdS/CdTe cell was prepared using the conventional NP treatment. With this treatment, the CdS/CdTe cell was dipped in a mixture of nitric and phosphoric acids for a duration of several tens of seconds to produce a tellurium rich surface on top of the CdTe as the back buffer layer. The back electrode was then applied by vapor deposition to this buffer layer to complete the cell fabrication. FIG. 4 shows the current-voltage characteristics of a series of cells with various CdTe thicknesses from 1.8 to 6.0 μm and a back buffer layer produced by NP treatment.

Table 3 summarizes the cell performance parameters. It is noted that the V_{OC}, J_{SC}, FF and the overall efficiency are lower for the cells with a thin CdTe layer (2.75 μm and below). Attempts to make cells with a CdTe layer of thickness below 1.8 μm resulted in shorted cells, apparently due to pin-hole formation caused by the solution NP treatment.

TABLE 3
Performance parameters of CdS/CdTe cells with
a back buffer layer produced NP treatment

| Thickness | NP | Thickness | | | | |
|---|---|---|---|---|---|---|
| of CdTe | treatment | of Ni | | | | |
| films | duration | electrode | J_{SC} | V_{OC} | FF | η_{eff} |
| (μm) | (s) | (nm) | (mA/cm²) | (mV) | (%) | (%) |
| 1.8 | 25 | 300 | 17.9 | 708 | 57.2 | 7.2 |
| 2.75 | 35 | 300 | 19.1 | 685 | 50.8 | 6.7 |
| 3.2 | 40 | 300 | 21.6 | 766 | 63.4 | 10.5 |
| 4.3 | 40 | 300 | 21.5 | 790 | 67.0 | 11.4 |
| 6.0 | 40 | 300 | 21.9 | 767 | 63.8 | 10.7 |

### Example 4

The Example discusses photovoltaic cells of the present invention where the back buffer layer comprises MoOₓ.

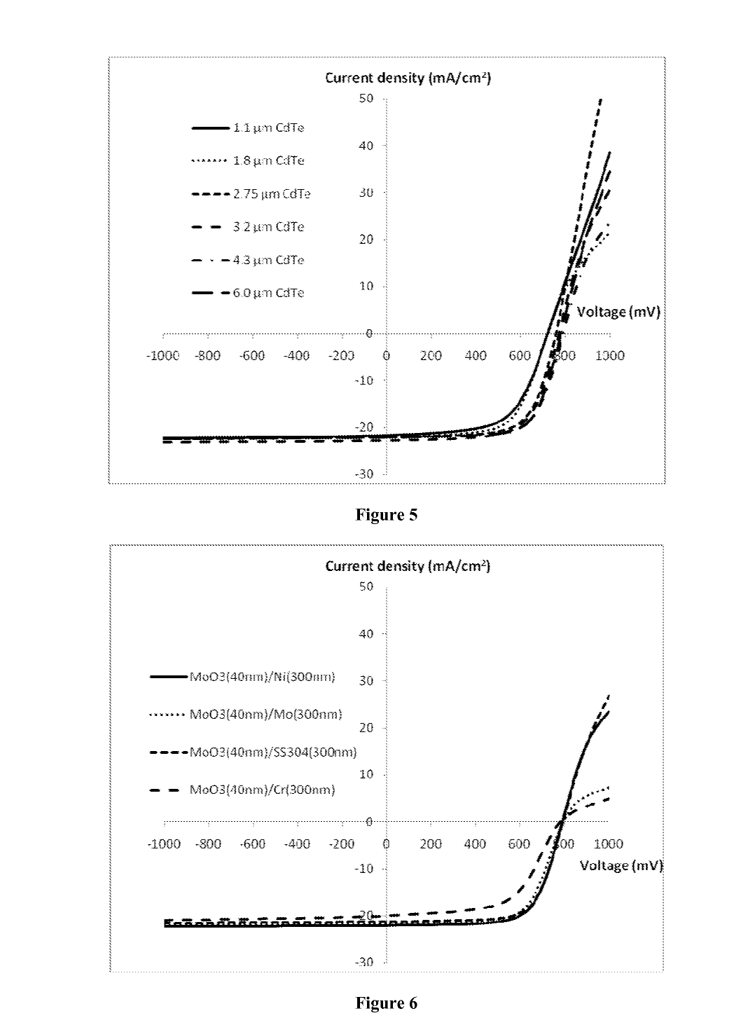

In this example, the back buffer layer for the CdS/CdTe cell was a thin layer of MoOₓ prepared by a dry deposition method. The MoOₓ film was deposited by vapor deposition in a vacuum chamber using MoO₃ powder as the vapor source and a resistive element as the heat source. MoOₓ film was typically deposited at a rate of 1 nm per sec onto the CdTe surface. After the deposition of MoOₓ layer, the back electrode was then applied by vapor deposition to this buffer layer to complete the cell fabrication. FIG. 5 shows the current-voltage characteristics of a series of cells with various CdTe thicknesses from 1.1 to 6.0 μm. Table 4 summarizes the cell performance parameters. It is noted that the V_{OC}, J_{SC}, FF and the overall efficiency remain relatively high even for cells with a thin CdTe layer (2.75 μm and below). Non-shorted cells were made with a CdTe layer as thin as 1.1 μm. This example demonstrates the advantage of MoOₓ in producing CdS/CdTe cells with a thin CdTe layer, thus substantially conserving CdTe usage.

TABLE 4
Performance parameters of CdS/CdTe
cells with a MoOₓ back buffer layer

| Thickness | Thickness | Thickness | | | | |
|---|---|---|---|---|---|---|
| of CdTe | of MoOₓ | of Ni | | | | |
| film | buffer | electrode | J_{SC} | V_{OC} | FF | η_{eff} |
| (μm) | layer (nm) | (nm) | (mA/cm²) | (mV) | (%) | (%) |
| 1.1 | 50 | 300 | 21.7 | 722 | 60.7 | 9.5 |
| 1.8 | 40 | 300 | 21.8 | 721 | 64.7 | 10.2 |
| 2.75 | 50 | 300 | 22.5 | 758 | 68.2 | 11.6 |
| 3.2 | 50 | 300 | 22.8 | 771 | 66.4 | 11.7 |
| 4.3 | 40 | 300 | 22.0 | 791 | 69.0 | 12.0 |
| 6.0 | 25 | 300 | 22.0 | 780 | 70.0 | 12.0 |

### Example 5

### Example of Photovoltaic Cells Fabricated with MoOₓ as the Back Buffer Layer And Various Metals as the Back Electrode

This example illustrates that with MoOₓ as the back buffer layer, various metals can be used as the back contact electrode. FIG. 6 shows the current-voltage characteristics of the CdS/CdTe cells with Ni, Mo, stainless steel 304, and Cr as the back contact electrode. It is noted that V_{OC}, J_{SC}, FF and the overall efficiency are generally high. It is noteworthy that inexpensive alloys such as stainless steel are also useful.

TABLE 5
Performance parameters of CdS/CdTe cells with MoOₓ as the
back buffer layer and various metals as the back electrode.

| Thickness | Thickness | | | | | |
|---|---|---|---|---|---|---|
| of CdTe | of MoOₓ | | | | | |
| film | buffer | Electrode | J_{SC} | V_{OC} | FF | η_{eff} |
| (μm) | layer (nm) | (nm) | (mA/cm²) | (mV) | (%) | (%) |
| 6.0 | 40 | Ni | 22.0 | 791 | 69.0 | 12.0 |
| | | (300) | | | | |
| 6.0 | 40 | Mo | 21.7 | 795 | 67.2 | 11.6 |
| | | (300) | | | | |
| 6.0 | 40 | SS304 | 21.2 | 790 | 69.7 | 11.7 |
| | | (300) | | | | |
| 6.0 | 40 | Cr | 20.0 | 785 | 58.0 | 9.1 |
| | | (300) | | | | |

While the invention has been particularly shown and described with reference to specific embodiments (some of which are preferred embodiments), it should be understood by those having skill in the art that various changes in form and detail may be made therein without departing from the spirit and scope of the present invention as disclosed herein.

What is claimed is:

1. A photovoltaic cell comprising, in sequence,
a) a substrate, wherein the substrate is at least semitransparent;
b) a front electrode, wherein the front electrode is at least semitransparent;
c) optionally, a front buffer layer;
d) a n-type semiconductor layer;
e) a p-type semiconductor layer;
f) a back buffer layer, wherein the back buffer layer is a metal oxide; and
g) a back electrode.

2. A photovoltaic cell as in claim 1 wherein the n-type semiconductor layer is cadmium sulfide or a cadmium sulfide alloy.

3. A photovoltaic cell as in claim 1 wherein the p-type semiconductor layer is cadmium telluride or a cadmium telluride alloy.

4. A photovoltaic cell as in claim 1 wherein the metal oxide has a work function greater than 5.8 eV.

5. A photovoltaic cell as in claim 1 wherein the metal oxide is a stoichiometric or a nonstoichiometric metal oxide.

6. A photovoltaic cell as in claim 1 wherein the metal oxide is selected from the group consisting of molybdenum oxide, nickel oxide, tungsten oxide, vanadium oxide and tantalum oxide.

7. A photovoltaic cell as in claim 1 wherein the metal oxide is a nonstoichiometric form of molybdenum oxide or nickel oxide.

8. A photovoltaic cell as in claim 1 wherein the metal oxide is a stoichiometric form of molybdenum oxide or nickel oxide.

9. A photovoltaic cell as in claim 1 wherein the metal oxide is deposited by a physical deposition method selected from the group consisting of sputtering, e-beam evaporation, and resistive heating evaporation.

10. A photovoltaic cell as in claim 1 wherein the p-type semiconductor layer is cadmium telluride and the p-type semiconductor layer is deposited by close-space sublimation.

11. A photovoltaic cell as in claim 1 wherein the back electrode is a metal film, wherein the metal is selected from the group consisting of nickel, molybdenum, chromium and stainless steel.

12. A photovoltaic cell as in claim 6 wherein the metal oxide is molybdenum oxide.

13. A photovoltaic cell as in claim 6 wherein the metal oxide is nickel oxide.

14. A photovoltaic cell as in claim 6 wherein the metal oxide is tungsten oxide.

15. A photovoltaic cell as in claim 6 wherein the metal oxide is vanadium oxide.

16. A photovoltaic cell as in claim 6 wherein the metal oxide is tantalum oxide.
